(19) United States
(12) Patent Application Publication
(10) Pub. No.: US 2026/0245510 A1
(43) Pub. Date: Aug. 20, 2026

(54) PIXEL CIRCUIT AND DRIVING METHOD THEREOF, DISPLAY PANEL, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Miao WANG, Beijing (CN); Sifei AI, Beijing (CN); Zhiliang JIANG, Beijing (CN); Gukhwan SONG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/869,853

(22) PCT Filed: Aug. 14, 2024
(86) PCT No.: PCT/CN2024/112179

§ 371 Date: Nov. 27, 2024

(30) Foreign Application Priority Data
Sep. 25, 2023 (WO) PCT/CN2023/120988
Apr. 10, 2024 (CN) 202410433916.X

(51) Int. Cl. G09G 3/3233; G09G 3/20; G09G 3/3266; G11C 19/28

(52) U.S. Cl. CPC G09G 3/3233; G11C 19/287; G09G 3/2007; G09G 3/3266; G09G 2300/0819; G09G 2300/0861; G09G 2310/0286; G09G 2310/08; G09G 2320/0242; G09G 2320/0247; G09G 2320/0252; G09G 2320/0257; G09G 2340/0435

(57) ABSTRACT

A pixel circuit includes a driving sub-circuit, a data writing sub-circuit, a first reset sub-circuit and a second reset sub-circuit. The pixel circuit has a first reset period and a data writing period, and the first reset period precedes the data writing period. The first reset sub-circuit is configured to, in the first reset period, transmit a first initialization signal received at a first initialization signal terminal to a first node in response to a first reset signal received at a first reset signal terminal. The second reset sub-circuit is configured to, in the first reset period, transmit a second initialization signal received at a second initialization signal terminal in response to a second reset signal received at a second reset signal terminal. In the first reset period, a voltage of the second initialization signal is greater than a voltage of the first initialization signal.

This application claims priorities to International Patent Application No. PCT/CN 2023/120988, filed on Sep. 25, 2023 and Chinese Patent Application No. 202410433916.X, filed on Apr. 10, 2024, which are incorporated herein by reference in their entirety.

### TECHNICAL FIELD

The present disclosure relates to the field of display technologies, and in particular, to a pixel circuit, a driving method of a pixel circuit, a display panel, and a display apparatus.

### BACKGROUND

With the rapid development of display technologies, display apparatuses have gradually come throughout people's lives. Organic light-emitting diodes (OLEDs) are widely used in smart products such as mobile phones, televisions, and notebook computers due to their advantages of self-luminescence, low power consumption, wide viewing angle, fast response, high contrast, and flexible display.

### SUMMARY

In an aspect, a pixel circuit is provided. The pixel circuit has a first reset period and a data writing period, the first reset period preceding the data writing period. The pixel circuit includes a driving sub-circuit, a data writing sub-circuit, a first reset sub-circuit and a second reset sub-circuit.

The driving sub-circuit is connected to a first node, a second node and a third node. The driving sub-circuit is configured to control a circuit between the second node and the third node to be turned on or off under control of a voltage of the first node. The data writing sub-circuit is connected to a first scan signal terminal, a data signal terminal and the second node. The data writing sub-circuit is configured to, in the data writing period, transmit a data signal received at the data signal terminal to the second node in response to a first scan signal received at the first scan signal terminal.

The first reset sub-circuit is connected to a first initialization signal terminal, a first reset signal terminal and the first node. The first reset sub-circuit is configured to, in the first reset period, transmit a first initialization signal received at the first initialization signal terminal to the first node in response to a first reset signal received at the first reset signal terminal. The second reset sub-circuit is connected to a second initialization signal terminal, a second reset signal terminal and the second node. The second reset sub-circuit is configured to, in the first reset period, transmit a second initialization signal received at the second initialization signal terminal to the second node in response to a second reset signal received at the second reset signal terminal. In the first reset period, a voltage of the second initialization signal is greater than a voltage of the first initialization signal.

In some embodiments, in the first reset period, an absolute value of a difference between the voltage of the second initialization signal and the voltage of the first initialization signal is in a range of 10 V to 13 V, inclusive.

In some embodiments, the pixel circuit further has a second reset period and a first light-emitting period, the second reset period intervening between the data writing period and the first light-emitting period. The second reset sub-circuit is further configured to, in the second reset period, transmit the second initialization signal received at the second initialization signal terminal to the second node in response to the second reset signal received at the second reset signal terminal.

In some embodiments, the pixel circuit has a first refresh rate and a second refresh rate, and the second refresh rate is less than the first refresh rate; at the first refresh rate, one frame includes one refresh cycle; at the second refresh rate, one frame further includes at least one holding cycle; the at least one holding cycle follows the refresh cycle; the holding cycle includes at least one third reset period and a second light-emitting period; the at least one third reset period precedes the second light-emitting period.

The pixel circuit further includes a third reset sub-circuit and a first storage sub-circuit. The third reset sub-circuit is connected to a fourth node, a third reset signal terminal and a third initialization signal terminal. The fourth node is configured to be connected to an anode of a light-emitting device. The third reset sub-circuit is configured to, in the first reset period and the third reset period, transmit a third initialization signal received at the third initialization signal terminal to the fourth node in response to a third reset signal received at the third reset signal terminal. The first storage sub-circuit is connected to a first voltage signal terminal and the fourth node. The first storage sub-circuit is configured to, in the first reset period and the third reset period, pull up or pull down a voltage of the fourth node in response to a first voltage signal received at the first voltage signal terminal.

A voltage of one of the third reset signal and the first voltage signal in the refresh cycle is greater than the voltage of one of the third reset signal and the first voltage signal in the holding cycle; and a voltage of another of the third reset signal and the first voltage signal in the holding cycle is greater than the voltage of another of the third reset signal and the first voltage signal in the refresh cycle.

In some embodiments, a signal of the first voltage signal terminal is the same as a signal of the second initialization signal terminal.

In some embodiments, a signal of the third reset signal terminal is the same as a signal of the second reset signal terminal.

In some embodiments, the first storage sub-circuit includes a first capacitor, a first plate of the first capacitor is connected to the first voltage signal terminal, and a second plate of the first capacitor is connected to the fourth node.

In some embodiments, the first reset sub-circuit includes a plurality of first transistors connected in series, and control electrodes of the first transistors are connected to the first reset signal terminal. Among two first transistors located on two ends of the plurality of first transistors connected in series, a first electrode of one first transistor is connected to the first initialization signal terminal, and a second electrode of another first transistor is connected to the first node.

The second reset sub-circuit includes a second transistor. A first electrode of the second transistor is connected to the second reset signal terminal, a second electrode of the second transistor is connected to the second node, and a control electrode of the second transistor is connected to the second reset signal terminal.

The first transistors and the second transistor are P-type transistors. A non-operating voltage of the first reset signal received at the first reset signal terminal is less than a non-operating voltage of the second reset signal received at the second reset signal terminal.

In some embodiments, the pixel circuit further includes a compensation sub-circuit. The compensation sub-circuit is connected to the first node, the third node and a second scan signal terminal. The compensation sub-circuit is configured to, in the data writing period, transmit a voltage of the third node to the first node in response to a second scan signal received at the second scan signal terminal.

In some embodiments, the compensation sub-circuit includes a plurality of third transistors connected in series, and control electrodes of the third transistors are connected to the second scan signal terminal. Among two third transistors located on two ends of the plurality of third transistors connected in series, a second electrode of one third transistor is connected to the first node, and a first electrode of another third transistor is connected to the third node.

The second reset sub-circuit includes a second transistor; the second transistor and the third transistors are P-type transistors. A non-operating voltage of the second scan signal received at the second scan signal terminal is less than a non-operating voltage of the second reset signal received at the second reset signal terminal.

In some embodiments, one frame includes a light-emitting period, and the pixel circuit further includes a first light-emitting control sub-circuit and a second light-emitting control sub-circuit.

The first light-emitting control sub-circuit is connected to the second node, a first power signal terminal and a first enable signal terminal. The first light-emitting control sub-circuit is configured to, in the light-emitting period, transmit a first power signal received at the first power signal terminal to the second node in response to a first enable signal received at the first enable signal terminal.

The second light-emitting control sub-circuit is connected to the third node, a fourth node and a second enable signal terminal. The second light-emitting control sub-circuit is configured to, in the light-emitting period, transmit a voltage of the third node to the fourth node in response to a second enable signal received at the second enable signal terminal. The fourth node is configured to be connected to an anode of a light-emitting device.

In the light-emitting period, a start time of an operating voltage of the first enable signal precedes a start time of an operating voltage of the second enable signal.

In another aspect, a display panel is provided. The display panel includes a plurality of pixel circuits as described in any of the above embodiments. The plurality of pixel circuits are arranged in M rows and N columns; each row includes N pixel circuits arranged in a first direction; each column includes M pixel circuits arranged in a second direction; M>1, N>1, and M and N are integers.

In some embodiments, the pixel circuit includes a compensation sub-circuit; in the second direction, from a first row of pixel circuits to a last row of pixel circuits, M rows of pixel circuits are a 1st row of pixel circuits to an M-th row of pixel circuits.

The display panel further includes a first gate driver circuit, and the first gate driver circuit includes (M+Q) first shift registers in cascade. From a first-stage first shift register to a last-stage first shift register, the (M+Q) first shift registers are a 1st first shift register to an (M+Q)-th first shift register.

A first shift register includes a first signal output terminal; first reset signal terminals of a P-th row of pixel circuits are connected to a first signal output terminal of a P-th first shift register; second scan signal terminals of the P-th row of pixel circuits are connected to a first signal output terminal of a (P+Q)-th first shift register; P≤M, Q>0, and P and Q are integers.

In some embodiments, the pixel circuit includes a third reset sub-circuit; in the second direction, from a first row of pixel circuits to a last row of pixel circuits, M rows of pixel circuits are a 1st row of pixel circuits to an M-th row of pixel circuits.

The display panel further includes a second gate driver circuit, and the second gate driver circuit includes M second shift registers in cascade. From a first-stage second shift register to a last-stage second shift register, the M second shift registers are a 1st second shift register to an M-th second shift register; a second shift register includes a second signal output terminal; second reset signal terminals and third reset signal terminals of a P-th row of pixel circuits are connected to a second signal output terminal of a P-th second shift register; P≤M, and P is an integer.

In some embodiments, the pixel circuit includes a first light-emitting control sub-circuit and a second light-emitting control sub-circuit; in the second direction, from a first row of pixel circuits to a last row of pixel circuits, M rows of pixel circuits are a 1st row of pixel circuits to an M-th row of pixel circuits.

The display panel further includes a third gate driver circuit and a fourth gate driver circuit. The third gate driver circuit includes M third shift registers in cascade; from a first-stage third shift register to a last-stage third shift register, the M third shift registers are a 1st third shift register to an M-th third shift register; a third shift register includes a third signal output terminal; first enable signal terminals of a P-th row of pixel circuits are connected to a third signal output terminal of a P-th third shift register; P≤M, and P is an integer. The fourth gate driver circuit includes M fourth shift registers in cascade; from a first-stage fourth shift register to a last-stage fourth shift register, and the M fourth shift registers are a 1st fourth shift register to an M-th fourth shift register; a fourth shift register includes a fourth signal output terminal; second enable signal terminals of the P-th row of pixel circuits are connected to a fourth signal output terminal of a P-th fourth shift register; P≤M, and P is an integer.

In some embodiments, in the second direction, from a first row of pixel circuits to a last row of pixel circuits, M rows of pixel circuits are a 1st row of pixel circuits to an M-th row of pixel circuits.

The display panel further includes a fifth gate driver circuit, and the fifth gate driver circuit includes M fifth shift registers in cascade; from a first-stage fifth shift register to a last-stage fifth shift register, the M fifth shift registers are a 1st fifth shift register to an M-th fifth shift register; a fifth shift register includes a fifth signal output terminal; first scan signal terminals of a P-th row of pixel circuits are connected to a fifth signal output terminal of a P-th fifth shift register; P≤M, and P is an integer.

In yet another aspect, a display apparatus is provided. The display apparatus includes the display panel as described in any one of the above embodiments.

In yet another aspect, a driving method of a pixel circuit is provided. The method is used for driving the pixel circuit as described in any of the above embodiments. The method includes a first reset period and a data writing period. The first reset period precedes the data writing period. The first reset period includes a first sub-period and a second sub-period. The first sub-period precedes the second sub-period, or the first sub-period follows the second sub-period, or the first sub-period and the second sub-period at least partially overlap.

In the first sub-period, the first reset sub-circuit transmits the first initialization signal received at the first initialization signal terminal to the first node in response to the first reset signal received at the first reset signal terminal; and in the second sub-period, the second reset sub-circuit transmits the second initialization signal received at the second initialization signal terminal to the second node in response to the second reset signal received at the second reset signal terminal.

In some embodiments, the method further includes a second reset period and a first light-emitting period, the second reset period intervening between the data writing period and the first light-emitting period. In the second reset period, the second reset sub-circuit transmits the second initialization signal received at the second initialization signal terminal to the second node in response to the second reset signal received at the second In some embodiments, the pixel circuit further includes a third reset sub-circuit and a first storage sub-circuit. The pixel circuit has a first refresh rate and a second refresh rate, and the second refresh rate is less than the first refresh rate. At the first refresh rate, one frame includes one refresh cycle. At the second refresh rate, one frame includes one refresh cycle and at least one holding cycle, and the at least one holding cycle follows the refresh cycle. The holding cycle includes at least one third reset period and a second light-emitting period, and the at least one third reset period precedes the second light-emitting period.

In the first reset period and the third reset period, the third reset sub-circuit transmits a third initialization signal received at the third initialization signal terminal to the fourth node in response to a third reset signal received at the third reset signal terminal; and the first storage sub-circuit pulls up or pulls down a voltage of the fourth node in response to a first voltage signal received at the first voltage signal terminal. A voltage of one of the first reset signal and the first voltage signal in the refresh cycle is greater than the voltage of one of the first reset signal and the first voltage signal in the holding cycle; and a voltage of another of the first reset signal and the first voltage signal in the holding cycle is greater than the voltage of another of the first reset signal and the first voltage signal in the refresh cycle.

In some embodiments, the pixel circuit includes a first light-emitting control sub-circuit and a second light-emitting control sub-circuit. One frame includes a light-emitting period. In the light-emitting period, the first light-emitting control sub-circuit transmits a first power signal received at a first power signal terminal to the second node in response to a first enable signal received at a first enable signal terminal; and the second light-emitting control sub-circuit transmits a voltage of the third node to a fourth node in response to a second enable signal received at a second enable signal terminal. A start time of an operating voltage of the first enable signal precedes a start time of an operating voltage of the second enable signal.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of another display apparatus, in accordance with some embodiments;

FIG. 3 is a sectional view taken along the section line A-A in FIG. 1;

FIG. 4A is a structural diagram of a display panel, in accordance with some embodiments;

FIG. 4B is a structural diagram of another display panel, in accordance with some embodiments;

FIG. 5 is a sectional view taken along the section line C-C in FIG. 4A;

FIG. 6 is a box diagram showing a structure of a pixel circuit, in accordance with some embodiments;

FIG. 7 is a circuit diagram of the pixel circuit in FIG. 6;

FIG. 8 is a timing diagram of a pixel circuit, in accordance with some embodiments;

FIG. 9 is a timing diagram of another pixel circuit, in accordance with some embodiments;

FIG. 10 is a timing diagram of yet another pixel circuit, in accordance with some embodiments;

FIG. 11 is a timing diagram of yet another pixel circuit, in accordance with some embodiments;

FIG. 12 is a diagram showing test results of just noticeable color difference (JNCD) of a display panel, in accordance with some embodiments;

FIG. 13 is a diagram showing test results of flicker values of a display panel varying over time in the related art;

FIG. 14 is a diagram showing test results of flicker values of a display panel varying over time, in accordance with some embodiments; and

FIG. 15 is a structural diagram of yet another display panel, in accordance with some embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, terms such as “first” and “second” are only used for descriptive purposes, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “multiple”, “a plurality of” or “the plurality of” means two or more unless otherwise specified.

In the description of some embodiments, the terms such as “coupled” and “connected” and derivatives thereof may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if” is, optionally, construed to mean “when” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or value beyond those stated.

Considering measurement in question and errors associated with measurement of a particular quantity (i.e., limitations of a measurement system), the term such as “about”, “approximately”, or “substantially” as used herein includes a stated value and means within an acceptable range of deviation for a particular value as determined by a person of ordinary skill in the art. For example, “about” means within one or more standard deviations, or within ±30%, ±20%, ±10%, ±5% of the stated value.

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

In the specification, unless otherwise defined, all terms (including technical and scientific terms) used herein have the same meaning as commonly understood by a person of ordinary skill in the art. It will be further understood that unless expressly defined herein, terms (such as those defined in commonly used dictionaries) should be interpreted as having a meaning that is consistent with their meaning in the context of the related art, and should not be interpreted as an ideal or overly formal meaning.

In the present disclosure, terms such as “lower”, “below”, “above”, and “upper” are used to explain the relational association of components shown in the drawings. The terms may be relative concepts and described based on directions shown in the drawings, or may be described based on the order in which the process steps are formed, but are The term “opposite to” means that a first element and a second element may be directly or indirectly opposite. In the case where a third element is interposed between the first element and the second element, the first element and the second element may be understood as being indirectly opposite to each other although they are still opposite to each other.

In the embodiments of the present disclosure, the transistors may be thin film transistors (TFTs), field effect transistors (metal oxide semiconductors (MOSs)) or other switching devices with same characteristics, and the embodiments of the present disclosure will all be described by taking the TFTs as an example.

In the embodiments of the present disclosure, a control electrode of each TFT is a gate of the TFT, a first electrode of the TFT is one of a source and a drain of the TFT, and a second electrode of the TFT is another one of the source and the drain of the TFT. Since the source and the drain of the TFT may be symmetrical in structure, there may be no difference in structure between the source and the drain of the TFT. That is, there may be no difference in structure between the first electrode and the second electrode of the TFT in the embodiments of the present disclosure. For example, when the transistor is a P-type transistor, the first electrode of the transistor is the source, and the second electrode of the transistor is the drain. For example, when the transistor is an N-type transistor, the first electrode of the transistor is the drain, and the second electrode of the transistor is the source.

In the embodiments of the present disclosure, a capacitor may be a capacitor device that is fabricated separately through processes. For example, the capacitor is realized by manufacturing special capacitor electrodes, and each capacitor electrode of the capacitor may be realized by a metal layer, a semiconductor layer (e.g., doped with polysilicon), or the like. The capacitor may also be a parasitic capacitor formed by transistors, or by a transistor itself and another device or line, or by lines of a circuit itself.

In the embodiments of the present disclosure, nodes such as a first node, a second node and a third node do not represent actual components, but represent junction points of related electrical connections in circuit diagrams. That is, these nodes are nodes equivalent to the junction points of the related electrical connections in the circuit diagrams.

In the embodiments of the present disclosure, the term “operating voltage” refers to a voltage that causes an operated transistor included herein to be turned on; correspondingly, the term “non-operating voltage” refers a voltage that causes the operated transistor included therein to be turned off.

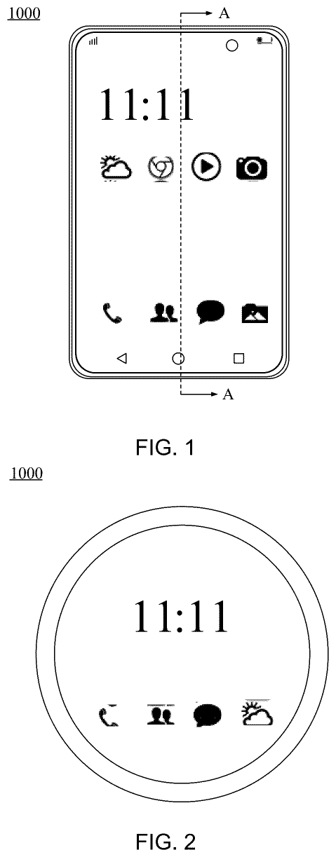

As shown in FIGS. 1 and 2, some embodiments of the present disclosure provide a display apparatus 1000. The display apparatus 1000 may be any apparatus that can display an image whether in motion (e.g., a video) or stationary (e.g., a still image), and whether textual or graphical.

For example, the display apparatus 1000 may be any product or component having a display function, such as a television, a notebook computer, a tablet computer, a mobile phone, a personal digital assistant (PDA), a navigator, a wearable device, or a virtual reality (VR) device.

For example, as shown in FIG. 1, the display apparatus 1000 may be a portable display product. For instance, the display apparatus 1000 may be a mobile phone shown in FIG. 1. For another example, referring to FIG. 2, the display apparatus 1000 may be a wearable device. For instance, the display apparatus 1000 may be a watch shown in FIG. 2.

It will be noted that, according to different application scenarios, the display apparatus 1000 may be a flat display apparatus, a curved display apparatus, a foldable display apparatus, etc., and a shape of the display surface of the display apparatus 1000 may be any one of a circular, elliptical, polygonal or irregular shape, which will not be specifically limited in the embodiments of the present disclosure.

Some embodiments of the present disclosure will be schematically described below by taking an example in which the display apparatus 1000 is a mobile phone shown in FIG. 1. However, implementations of the present disclosure are not limited to this.

In some embodiments, referring to FIG. 3, the display apparatus 1000 includes a display panel 100. The display panel 100 may include, for example, a display side and a non-display side that are opposite to each other. The display side is a side of the display panel 100 for display, which is an upper side in FIG. 3.

Type of the display panel 100 varies, which may be selected according to actual needs. For example, the display panel 100 may be an organic light-emitting diode (OLED) display panel, a quantum dot light-emitting diode (QLED) display panel, or a micro light-emitting diode (Micro LED) display panel, which will not be specifically limited in the embodiments of the present disclosure.

Some embodiments of the present disclosure will be schematically described below by taking an example in which the display panel 100 is an OLED display panel.

For example, as shown in FIG. 3, the display apparatus 1000 may further include a housing 200, a cover plate 300, a circuit board 400, and other electronic accessories.

Referring to FIG. 3, the cover plate 300 may be a single-layer glass cover plate, or may include a plurality of stacked cover sub-plates, which will not be specifically limited in the embodiments of the present disclosure.

As shown in FIG. 3, a longitudinal section of the housing 200 is, for example, U-shaped; the display panel 100 and the circuit board 400 are disposed in the housing 200; and the cover plate 300 is disposed on an opening of the housing 200. The circuit board 400 may be bonded to the display panel 100 at an end of the display side of the display panel 100, so as to provide required display signals for the display panel 100. For example, the circuit board 400 may be bent to the non-display side of the display panel 100, so as to reduce the bezel of the display panel 100 and increase the screen-to-body ratio.

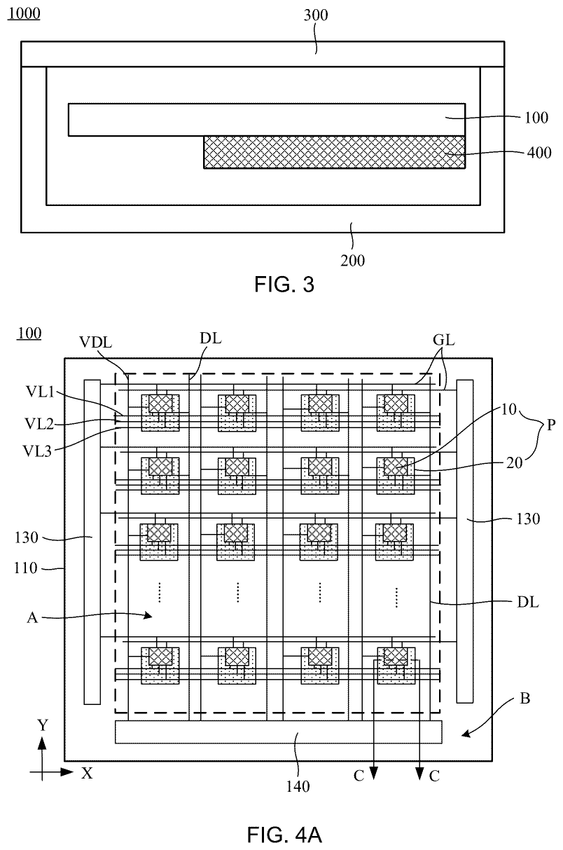

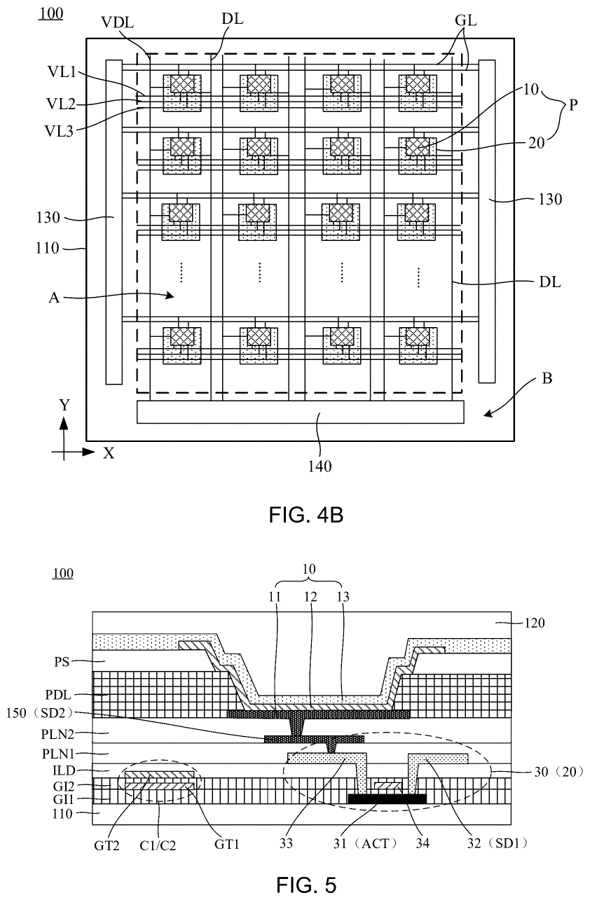

In some embodiments, referring to FIG. 4A, the display panel 100 has a display region A. The display region A is a region where images are displayed, and is configured to be provided therein with a plurality of sub-pixels P.

For example, referring to FIG. 4A, the display panel 100 includes: a substrate 110, and a plurality of sub-pixels P disposed on a side of the substrate 110 and located in the display region A.

Type of the substrate 110 varies, which may be selected according to actual needs.

For example, the substrate 110 may be a rigid substrate. For example, the rigid substrate may be a glass substrate or a polymethyl methacrylate (PMMA) substrate.

As another example, the substrate 110 may be a flexible substrate. For example, the flexible substrate may be a polyethylene terephthalate (PET) substrate, a polyethylene naphthalate (PEN) substrate, or a polyimide (PI) substrate.

Referring to FIGS. 4A and 5, the sub-pixel P includes a light-emitting device 10 and a pixel circuit 20. The pixel circuit 20 includes a plurality of transistors 30.

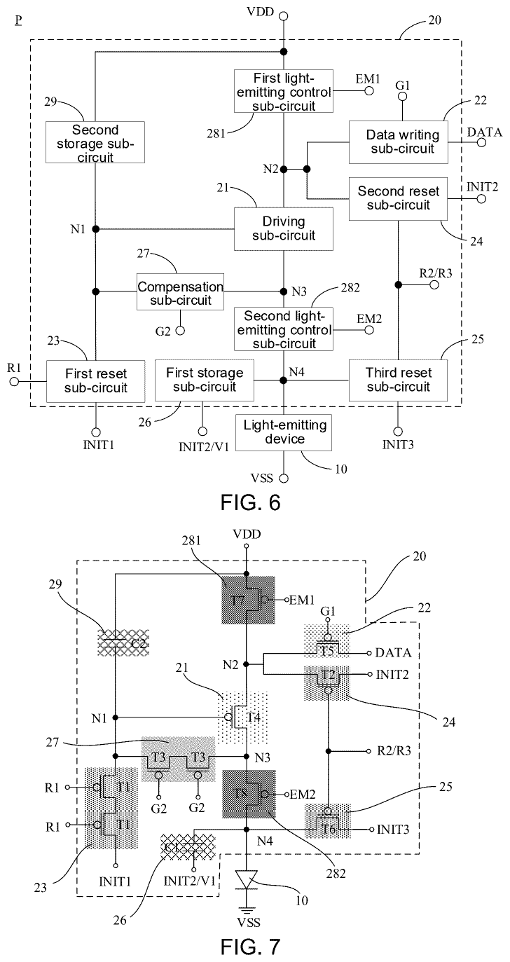

As shown in FIG. 5, the transistor 30 includes a semiconductor channel 31, a source 32, a drain 33 and a gate 34. The source 32 and the drain 33 are both in contact with the semiconductor channel 31. emitting functional layer 12 and a cathode 13. The anode 11 is electrically connected to a source 32 or a drain 33 of a transistor 30, and the cathode is connected to a second power signal terminal VSS (see FIG. 6). FIG. 5 illustrates an example in which the anode 11 is electrically connected to the drain 33 of the thin film transistor 30. It will be noted that a second power signal received by the second power signal terminal VSS may be a signal of a negative electrode of a direct current power supply.

It will be noted that the light-emitting functional layer 12 may include only a light-emitting layer; alternatively, the light-emitting functional layer 12 may include the light-emitting layer, and further include at least one of an electron transport layer (ETL), an electron injection layer (EIL), a hole transport layer (HTL) or a hole injection layer (HIL).

In the related art, when a display panel displays at a low frequency (for example, less than or equal to 60 Hz), human eyes can perceive flickering on display images. It has found through researches that during the display process of the display panel, an image of a previous moment (previous frame) usually remains in an image display of a current moment, resulting in a flickering display problem on the display images. Here, a frame refers to duration in which the display panel displays a still picture.

In light of this, referring to FIGS. 6 and 7, the pixel circuit 20 provided in some embodiments of the present disclosure includes a driving sub-circuit 21, a data writing sub-circuit 22, a first reset sub-circuit 23, and a second reset sub-circuit 24.

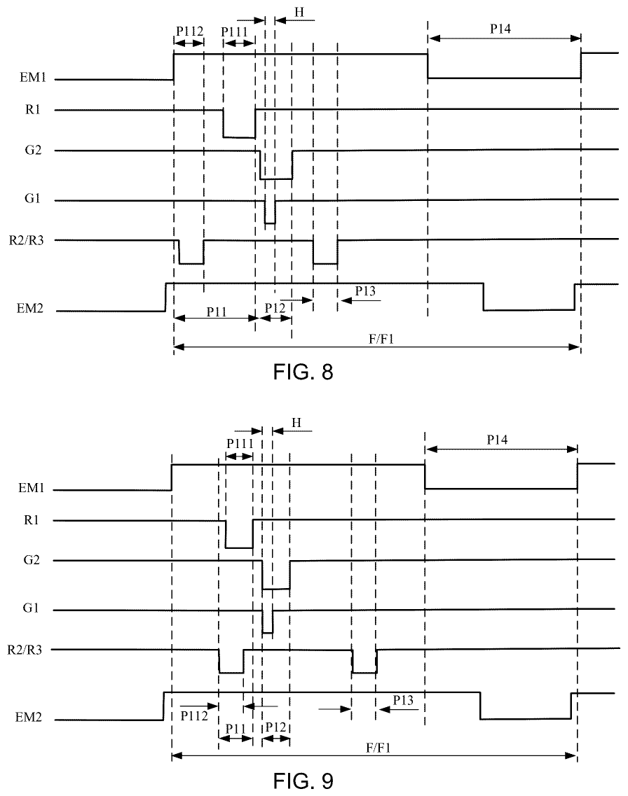

As shown in FIGS. 8, 9 and 10, a frame F includes a refresh cycle F1, the refresh cycle F1 includes a first reset period P11 and a data writing period P12, and the first reset period P11 precedes the data writing period P12.

In some examples, referring to FIG. 6, the driving sub-circuit 21 is coupled to a first node N1, a second node N2 and a third node N3. The driving sub-circuit 21 is configured to control a circuit between the second node N2 and the third node N3 to be turned on or off under control of a voltage of the first node N1, and generate a grayscale current signal according to the voltage of the first node N1 and a voltage of the second node N2.

For example, as shown in FIG. 7, the driving sub-circuit 21 includes a fourth transistor T4 (i.e. a driving transistor mentioned above). A first electrode of the fourth transistor T4 is connected to the second node N2, a second electrode of the fourth transistor T4 is connected to the third node N3, and a control electrode of the fourth transistor T4 is connected to the first node N1. The structure is simple.

In some examples, referring to FIG. 6, the data writing sub-circuit 22 is connected to a first scan signal terminal G1, a data signal terminal DATA and the second node N2. The data writing sub-circuit 22 is configured to, in the data writing period P12 (see FIG. 8), transmit a data signal received at the data signal terminal DATA to the second node N2 in response to a first scan signal received at the first scan signal terminal G1. In addition, the data signal of the second node N2 is written into the first node N1 after being compensated, so as to facilitate the driving sub-circuit 21 to generate a grayscale current signal. As for details, reference can be made to the following description.

For example, as shown in FIG. 7, the data writing sub-circuit 22 includes a fifth transistor T5. A first electrode of the fifth transistor T5 is connected to the data signal terminal DATA, a second electrode of the fifth transistor T5 is connected to the second node N2, and a control electrode of the fifth transistor T5 is connected to the first scan signal terminal G1.

In some examples, referring to FIG. 6, the first reset sub-circuit 23 is connected to a first initialization signal terminal INIT1, a first reset signal terminal R1, and the first node N1. The first reset sub-circuit 23 is configured to, in the first reset period P11 (see FIG. 8), transmit a first initialization signal received at the first initialization signal terminal INIT1 to the first node N1 in response to a first reset signal received at the first reset signal terminal R1, so as to reset the voltage of the first node N1, eliminate influence of a data signal in a previous frame F on the voltage of the first node N1, ameliorate the image sticking, reduce the flicker value of the display panel 100, and mitigate the problem that the human eye can perceive flickering of the display images.

For example, as shown in FIG. 7, the first reset sub-circuit 23 may include a plurality of first transistors T1 connected in series; control electrodes of the first transistors T1 are connected to the first reset signal terminal R1. Furthermore, for two first transistors T1 on two ends among the plurality of first transistors connected in series, a first electrode of one first transistor T1 is connected to the first initialization signal terminal INIT1, and a second electrode of another first transistor T1 is connected to the first node N1, so as to reduce leakage current between the first node N1 and the first initialization signal terminal INIT1.

For example, as shown in FIG. 7, the first reset sub-circuit 23 includes two first transistors T1 connected in series; among the two first transistors T1, a first electrode of one first transistor T1 is connected to the first initialization signal terminal INIT1, a second electrode of the one first transistor T1 is connected to a first electrode of another first transistor T1, and a second electrode of the another first transistor T1 is connected to the first node N1. In this case, under the condition of effectively reducing the leakage current between the first node N1 and the first initial inversion signal terminal INIT1, the first reset sub-circuit 23 includes a small number of first transistors T1, so that an occupied area of the pixel circuit 20 may be reduced.

In some examples, referring to FIG. 6, the second reset sub-circuit 24 is connected to a second initialization signal terminal INIT2, a second reset signal terminal R2, and the second node N2. The second reset sub-circuit 24 is configured to, in the first reset period P11 (see FIG. 8), transmit a second initialization signal received at the second initialization signal terminal INIT2 to the second node N2 in response to a second reset signal received at the second reset signal terminal R2, so as to reset the voltage of the second node N2, eliminate influence of the data signal in the previous frame F on the voltage of the second node N2, ameliorate the image sticking, reduce the flicker value of the display panel 100, and mitigate the problem that the human eye can perceive flickering of the display images.

For example, as shown in FIG. 7, the second reset sub-circuit 24 includes a second transistor T2. A first electrode of the second transistor T2 is connected to the second initialization signal terminal INIT2, a second electrode of the second transistor T2 is connected to the second node N2, and a control electrode of the second transistor T2 is connected to the second reset signal terminal R2. The structure is simple.

The first transistor T1 and the second transistor T2 may both be P-type transistors. A non-operating voltage of the first reset signal received at the first reset signal terminal R1 is less than a non-operating voltage of the second reset signal received at the second reset signal terminal R2. In this case, the non-operating voltage at the first reset signal terminal R1 is relatively small. During a process of switching from the operating voltage to the non-operating voltage, it may be possible to reduce the voltage rise of the circuit wires between the plurality of first transistors T1 connected in series, and in turn reduce the leakage current of the first node N1.

In addition, in the first reset period P11, a voltage of the second initialization signal is different from a voltage of the first initialization signal. For example, the voltage of the second initialization signal is greater than the voltage of the first initialization signal. In this case, before the data writing period P12, in the first reset period P11, the first reset sub-circuit 23 transmits the first initialization signal received at the first initialization signal terminal INIT1 to the first node N1, and the second reset sub-circuit 24 transmits the second initialization signal received at the second initialization signal terminal INIT2 to the second node N2, and the voltage of the second node N2 is greater than the voltage of the first node N1. Therefore, the driving sub-circuit 21 is in a strong negative bias state, which may improve the hysteresis effect of the driving sub-circuit 21. As a result, the image sticking is ameliorated, the flicker value of the display panel 100 is reduced, and the problem that the human eye can perceive flickering of the display images is mitigated.

In the first reset period P11, an absolute value of a difference between the voltage of the second initialization signal and the voltage of the first initialization signal may be, for example, in a range of 10 V to 13 V, inclusive. In this case, the just noticeable color difference (JNCD) may be less than or equal to 5.5, the color difference of the display panel 100 is small, and the display effect is good.

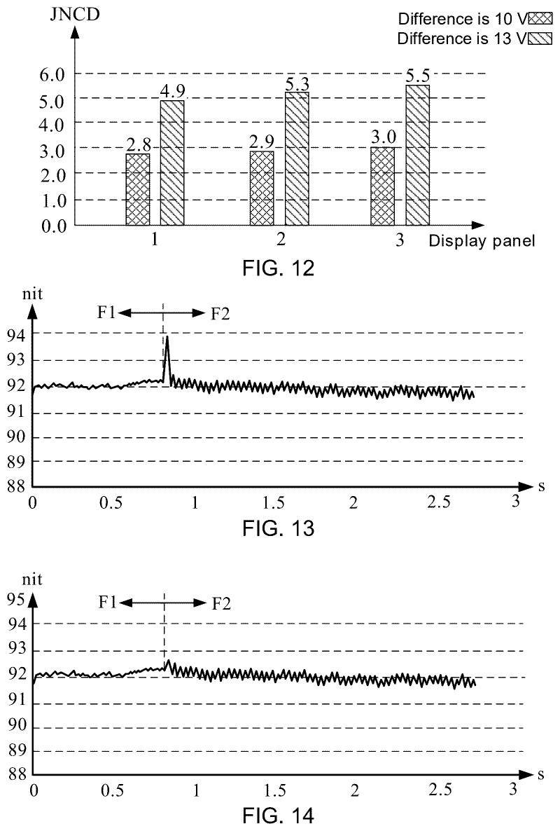

In the case where in the first reset period P11, the difference between the voltage of the second initialization signal and the voltage of the first initialization signal is 10 V, and in the case where in the first reset period P11, the difference between the voltage of the second initialization signal and the voltage of the first initialization signal is 13 V, three display panels 100 are tested to obtain the JNCD. The test results are shown in FIG. 12. In FIG. 12, the horizontal axis represents different display panels, and the vertical axis represents the JNCD.

It can be seen from FIG. 12, when the difference between the voltage of the second initialization signal and the voltage of the first initialization signal is 10 V, the JNCD may be less than or equal to 3.0; and when the difference between the voltage of the second initialization signal and the voltage of the first initialization signal is 13 V, the JNCD may be less than or equal to 5.5.

In some embodiments, referring to FIG. 8, the refresh cycle F1 further includes a second reset period P13 and a first light-emitting period P14, and the second reset period P13 intervenes between the data writing period P12 and the first light-emitting period P14.

On this basis, the second reset sub-circuit 24 is further configured to, in the second reset period P13, transmit the second initialization signal received at the second initialization signal terminal INIT2 to the second node N2 in response to the second reset signal received at the second reset signal terminal R2, so as to reset the voltage of the second node N2 and eliminate the influence of the data signal written in the previous data writing period P12 on the voltage of the second node N2.

In this case, after the data writing period P12, in the second reset period P13, the second reset sub-circuit 24 transmits the second initialization signal received at the second initialization signal terminal INIT2 to the second node N2, to eliminate the influence of the data signal written in the data writing period P12 on the voltage of the second node N2. In this way, it may be possible to eliminate the deviation of the generated grayscale current signal due to the grayscale difference of different sub-pixels P, and in turn improve the accuracy of the grayscale current signal and improve the display quality.

In some embodiments, referring to FIG. 6, the pixel circuit 20 further includes a third reset sub-circuit 25, and the third reset sub-circuit 25 is connected to a fourth node N4, a third reset signal terminal R3, and a third initialization signal terminal INIT3. The fourth node N4 is configured to be connected to the anode of the light-emitting device 10. The third reset sub-circuit 25 is configured to, in the first reset period P11 (see FIG. 8), transmit a third initialization signal received at the third initialization signal terminal INIT3 to the fourth node N4 in response to a third reset signal received at the third reset signal terminal R3.

In this case, in the first reset period P11, it may be possible to reset a voltage of the fourth node N, eliminate a voltage of the fourth node N4 in the previous frame F, eliminate the difference in voltage of the fourth node N4 caused by the grayscale difference of different sub-pixels P, ameliorate the difference in turn-on speed of the light-emitting devices 10 of different sub-pixels P, and improve the display quality.

For example, as shown in FIG. 7, the third reset sub-circuit 25 includes a sixth transistor T6. A first electrode of the sixth transistor T6 is connected to the third initialization signal terminal INIT3, a second electrode of the sixth transistor T6 is connected to the fourth node N4, and a control electrode of the sixth transistor T6 is connected to the third reset signal terminal R3. The structure is simple.

In addition, the signal at the third reset signal terminal R3 and the signal at the second reset signal terminal R2 may be the same. In this case, the third reset signal terminal R3 and the second reset signal terminal R2 may be connected to the same gate driver circuit through the same gate line, thereby simplifying the circuit structure. As for details, reference can be made to the following description.

In some embodiments, referring to FIG. 4A, the display panel 100 has a first refresh rate and a second refresh rate, and the second refresh rate is less than the first refresh rate. That is, the display panel 100 is a display panel 100 with a variable refresh rate, to meet the user's requirements for low power consumption and high refresh rate. In this case, the display panel 100 may, for example, display images at high and low variable frequency of 30 Hz, 40 Hz, 60 Hz and 120 Hz, or at high and low variable frequency of 40 Hz, 55 Hz, 82 Hz and 165 Hz, which will not be limited in the embodiments of the present disclosure.

That is, referring to FIGS. 7, 8 and 11, the pixel circuit 20 has a first refresh rate and a second refresh rate. At the first refresh rate, a frame F includes a refresh cycle F1. At the second refresh rate, a frame F further includes at least one holding cycle F2, and the at least one holding cycle F2 follows the refresh cycle F1. For example, at the second refresh rate, a frame F includes a refresh cycle F1 and a holding cycle F2.

As shown in FIG. 11, the holding cycle F2 includes at least one third reset period P21 and a second light-emitting period P22, and the at least one third reset period P21 precedes the second light-emitting period P22. For example, as shown in FIG. 11, the holding cycle F2 includes two third reset periods P21 and one second light-emitting period P22. Thus, the third reset signal changes periodically, which facilitates design. In addition, the voltage of the fourth node N4 (see FIG. 7) may be reset twice in the holding cycle F2, so that the influence of the data signal of the previous refresh cycle F1 on the voltage of the fourth node N4 (see FIG. 7) may be well eliminated, which may further improve the display effect.

On this basis, the third reset sub-circuit 25 is further configured to, in the third reset period P21, transmit the third initialization signal received at the third initialization signal terminal INIT3 to the fourth node N4 in response to the third reset signal received at the third reset signal terminal R3, so as to avoid the threshold voltage shift caused by the long-term bias of the fourth transistor T4 of the driving sub-circuit 21. In addition, it may be possible to reset the voltage of the fourth node N4, eliminate the voltage of the fourth node N4 in the previous refresh cycle F1, eliminate the difference in voltage of the fourth node N4 caused by the grayscale difference of different sub-pixels P, and ameliorate the difference in turn-on speed of the light-emitting devices 10 of different sub-pixels P. As a result, the flicker value of the display panel 100 is reduced, and the problem that the human eye can perceive flickering of the display images is mitigated.

In addition, referring to FIGS. 6 and 11, the voltage of the third reset signal in the refresh cycle F1 is different from the voltage of the third reset signal in the holding cycle F2. In this case, the pixel circuit 20 further includes a first storage sub-circuit 26, and the first storage sub-circuit 26 is connected to a first voltage signal terminal V1 and the fourth node N4. The first storage sub-circuit 26 is configured to, in the first reset period P11 and the third reset period P21, pull up or pull down the voltage of the fourth node N4 in response to a first voltage signal received at the first voltage signal terminal V1.

For example, as shown in FIG. 7, the first storage sub-circuit 26 includes a first capacitor C1. A first plate of the first capacitor C1 is connected to the first voltage signal terminal V1, and a second plate of the first capacitor C1 is connected to the fourth node N4. The structure is simple, and the response is fast.

In addition, for one of the third reset signal and the first voltage signal, its voltage in the refresh cycle F1 is greater than its voltage in the holding cycle F2; and for another of the third reset signal and the first voltage signal, its voltage in the holding cycle F2 is greater than its voltage in the refresh cycle F1. For example, the voltage of the third reset signal in the refresh cycle F1 is greater than the voltage of the third reset signal in the holding cycle F2, and the voltage of the first voltage signal in the holding cycle F2 is greater than the voltage of the first voltage signal in the refresh cycle F1.

In this case, in the third reset period P21, the first storage sub-circuit 26 may pull down the voltage of the fourth node N4 to reduce the influence of the third reset signal on the voltage rise of the fourth node N4 in the third reset period P21, thereby reducing the sudden change in turn-on brightness of the light-emitting device 10 during the switching between the refresh cycle F1 and the holding cycle F2. As a result, the flicker value of the display panel 100 is reduced, and the problem that the human eye can perceive flickering of the display images is mitigated.

FIG. 13 is a diagram showing test results of flicker values of a display panel varying over time in the related art. FIG. 14 is a diagram showing test results of flicker values of a display panel varying over time according to some embodiments. In FIG. 13, the pixel circuit of the display panel in the related art does not include the first storage sub-circuit. In FIG. 14, the pixel circuit of the display panel includes the first storage sub-circuit.

As can be seen from FIGS. 13 and 14, the first storage sub-circuit 26 may significantly reduce the sudden change in turn-on brightness of the light-emitting device 10 (see FIG. 5) during the switching between the refresh cycle F1 and the holding cycle F2. As a result, the flicker value of the display panel 100 (see FIG. 5) is reduced, and the problem that the human eye can perceive flickering of the display images is mitigated.

The signal at the first voltage signal terminal V1 may be the same as the signal at the second initialization signal terminal INIT2. That is, the voltage of the second initialization signal terminal INIT2 in the holding cycle F2 may be greater than the voltage of the second initialization signal terminal INIT2 in the refresh cycle F1, for example. In this case, the first voltage signal terminal V1 and the second initialization signal terminal INIT2 may be connected to the same gate driver circuit through the same gate line, thereby simplifying the circuit structure. As for details, reference may be made to the following description.

In some embodiments, referring to FIG. 6, the pixel circuit 20 further includes a compensation sub-circuit 27, and the compensation sub-circuit 27 is connected to the first node N1, the third node N3, and a second scan signal terminal G2. The compensation sub-circuit 27 is configured to, in the data writing period P12 (see FIG. 8), transmit a voltage of the third node N3 to the first node N1 in response to a second scan signal received at the second scan signal terminal G2, so as to write a compensated data signal into the first node N1.

For example, as shown in FIG. 7, the compensation sub-circuit 27 includes a plurality of third transistors T3 connected in series, and control electrodes of the third transistors T3 are connected to the second scan signal terminal. Among two third transistors T3 located on two ends of the plurality of third transistors T3 connected in series, a first electrode of one third transistor T3 is connected to the third node N3, and a second electrode of another third transistor T3 is connected to the first node N1, so as to reduce the leakage current between the first node N1 and the third node N3.

For example, as shown in FIG. 7, the compensation sub-circuit 27 includes two third transistors T3 connected in series. Among the two third transistors T3, a first electrode of one third transistor T3 is connected to the third node N3, a second electrode of the one third transistor T3 is connected to a first electrode of another third transistor T3, and a second electrode of the another third transistor T3 is connected to the first node N1. In this case, under the condition of effectively reducing the leakage current between the first node N1 and the third node N3, the compensation sub-circuit 27 includes a small number of third transistors T3, so that an occupied area of the pixel circuit 20 may be reduced.

The second transitor T2 and the third transistor T3 may both be P-type transistors. A non-operating voltage of the second scan signal received at the second scan signal terminal G2 is less than a non-operating voltage of the second reset signal received at the second reset signal terminal R2. In this case, the non-operating voltage at the second scan signal terminal G2 is relatively small. During the process of switching from the operating voltage to the non-operating voltage, it may be possible to reduce the voltage rise of the circuit wires between the plurality of third transistors T3 connected in series, and in turn reduce the leakage current of the first node N1.

In some embodiments, referring to FIG. 6, the pixel circuit 20 further includes a first light-emitting control sub-circuit 281 and a second light-emitting control sub-circuit 282.

In some examples, referring to FIG. 6, the first light-emitting control sub-circuit 281 is connected to the second node N2, a first power signal terminal VDD, and a first enable signal terminal EM1. The first light-emitting control sub-circuit 281 is configured to, in a light-emitting period (a first light-emitting period P14 and/or a second light-emitting period P22), transmit a first power signal at the first power signal terminal VDD to the second node N2 in response to a first enable signal received at the first enable signal terminal EM1, so that the driving sub-circuit 21 may generate the grayscale current signal according to the voltage of the first node N1 and the voltage of the second node N2. It will be noted that the first power signal may be a signal of a positive electrode of the direct current power supply.

For example, as shown in FIG. 7, the first light-emitting control sub-circuit 281 includes a seventh transistor T7. A first electrode of the seventh transistor T7 is connected to the first power signal terminal VDD, a second electrode of the seventh transistor T7 is connected to the second node N2, and a control electrode of the seventh transistor T7 is connected to the first enable signal terminal EM1. The structure is simple.

In some examples, referring to FIG. 6, the second light-emitting control sub-circuit 282 is connected to the third node N3, the fourth node N4, and a second enable signal terminal EM2. The second light-emitting control sub-circuit 282 is configured to, in a light-emitting period (the first light-emitting period P14 and/or the second light-emitting period P22), transmit the voltage of the third node N3 to the fourth node N4 in response to a second enable signal received at the second enable signal terminal EM2, so as to transmit the grayscale current signal to the light-emitting device 10 to drive the light-10 to emit light.

For example, as shown in FIG. 7, the second light-emitting control sub-circuit 282 includes an eighth transistor T8. A first electrode of the eighth transistor T8 is connected to the third node N3, a second electrode of the eighth transistor T8 is connected to the fourth node N4, and a control electrode of the eighth transistor T8 is connected to the second enable signal terminal EM2. The structure is simple.

In the light-emitting period (the first light-emitting period P14 and/or the second light-emitting period P22), a start time of an operating voltage of the first enable signal, for example, may precede a start time of an operating voltage of the second enable signal. In this case, the first light-emitting control sub-circuit 281 is turned on first, and the grayscale current signal may be written into the third node N3 in advance. Then, the second light-emitting control sub-circuit 282 is turned on, and the grayscale current signal may be quickly written from the third node N3 into the fourth node N4 to drive the light-emitting device 10. As a result, the display quality of the display panel 100 may be improved.

In some embodiments, referring to FIG. 6, the pixel circuit 20 further includes a second storage sub-circuit 29, and the second storage sub-circuit 29 is connected to the first power signal terminal VDD and the first node N1. The second storage sub-circuit 29 is configured to store the voltage of the first node N1, playing a role of voltage stabilization.

For example, as shown in FIG. 7, the second storage sub-circuit 29 includes a second capacitor C2. A first plate of the second capacitor C2 is connected to the first power signal terminal VDD, and a second electrode plate of the second capacitor C2 is connected to the first node N1. The structure is simple.

Referring to FIG. 4A, the display panel 100 in the embodiments of the present disclosure includes the pixel circuit 20 as described in any of the above embodiments. For example, the display panel 100 includes a plurality of pixel circuits 20 arranged in a plurality of rows and a plurality of columns, each row includes multiple pixel circuits 20 arranged in a first direction X, and each column includes multiple pixel circuits 20 arranged in a second direction Y. The first direction X and the second direction Y intersect. For example, the first direction X may be perpendicular to the second direction Y.

It will be noted that, the first direction X may be, for example, a row direction in which the plurality of pixel circuits are arranged, and the second direction Y may be, for example, a row direction in which the plurality of pixel circuits 20 are arranged.

Some embodiments of the present disclosure will be exemplarily described below by taking an example in which all pixel circuits 20 are arranged in a plurality of rows and a plurality of columns, but the implementations of the present disclosure are not limited thereto.

On this basis, as shown in FIG. 4A, the display panel 100 further includes gate lines GL, data lines DL, first power lines VDL, first initialization signal lines VL1, second initialization signal lines VL2, and third initialization signal lines VL3.

As shown in FIG. 4A, each gate line GL extends substantially in the first direction X, and is configured to transmit a control signal. The control signal includes any one of the first scan signal, the second scan signal, the first reset signal, the second reset signal, the third reset signal, the first enable signal, and the second enable signal. For example, a gate line GL may be connected to any one of first scan signal terminals G1, second scan signal terminals G2, first reset signal terminals R1, second reset signal terminals R2, third reset signal terminals R3, first enable signal terminals EM1 or second enable signal terminals EM2 of a row of pixel circuits 20.

As shown in FIGS. 4A and 6, the data lines DL extend substantially in the second direction Y, and are configured to transmit data signals. For example, a data line DL may be connected to data signal terminals DATA of a column of pixel circuits 20.

As shown in FIGS. 4A and 6, the first power lines VDL extend substantially in the second direction Y, and are configured to transmit first power voltage signals. A first power line VDL, for example, may be connected to first voltage signal terminals VDD of a column of pixel circuits 20.

As shown in FIGS. 4A and 6, the first initialization signal lines VL1, the second initialization signal lines VL2, and the third initialization signal lines VL3, for example, may extend substantially in the first direction X, and are configured to transmit first initialization signals, second initialization signals, and third initialization signals, respectively. A first initialization signal line VL1, a second initialization signal line VL2, and a third initialization signal line VL3, for example, may be respectively connected to first initialization signal terminals INIT1, second initialization signal terminals INIT2, and third initialization signal terminals INIT3 of a column of pixel circuits 20.

In some embodiments, as shown in FIG. 5, in a direction perpendicular to the substrate 110 and away from the substrate 110, the display panel 100 includes the substrate 110, a semiconductor layer ACT, a first gate insulating layer GI1, a first gate conductive layer GT1, a second gate insulating layer GI2, a second gate conductive layer GT2, an interlayer dielectric layer ILD, a first source-drain conductive layer SD1, a first planarization layer PLN1, a second source-drain conductive layer SD2, and a second planarization layer PLN2.

On this basis, referring to FIGS. 4A and 5, the semiconductor channels 31 of the transistors 30, for example, may be located in the semiconductor layer ACT. The gate lines GL, the gates 34 of the transistors and first plates of the capacitors (the first capacitors C1 and the second capacitors C2), for example, may be located in the first gate conductive layer GT1. Second plates of the capacitors (the first capacitors C1 and the second capacitors C2), the first initialization signal lines VL1, the second initialization signal lines VL2, and the third initialization signal lines VL3, for example, may be located in the second gate conductive layer GT2. The sources 32 and the drains 33 of the transistors 30 and the first power lines VDL, for example, may be located in the first source-drain conductive layer SD1. The data lines DL, for example, may be located in the second source-drain conductive layer SD2.

In some embodiments, as shown in FIG. 5, the display panel 100 further includes a pixel defining layer PDL, the pixel defining layer PDL is provided therein with a plurality of openings, and a light-emitting device 10 is located in an opening.

In some embodiments, as shown in FIG. 5, the display panel 100 further includes spacers PS. The spacer PS may be disposed between the pixel defining layer PDL and the light-emitting function layer 12, so as to support a mask during the process.

In some embodiments, referring to FIG. 5, the display panel 100 further includes an encapsulation layer 120. The encapsulation layer 120 is disposed on a side of the light-emitting devices 10 away from the substrate 110 to reduce the risk of water and oxygen corrosion. The encapsulation layer 120 may be an encapsulation film or an encapsulation substrate, which will not be specifically limited in the embodiments of the present disclosure.

In some embodiments, referring to FIG. 4A, the display panel 100 further has a peripheral region B, and the peripheral region B is disposed on at least one side of the display region A. The peripheral region B is a region where no image is displayed and is configured to be provided therein with gate driver circuit(s) 130, a source driver circuit 140, etc. FIG. 4A illustrates an example in which the peripheral region B is arranged around the display region A.

For example, referring to FIG. 4A, the display panel 100 includes the gate driver circuit(s) 130, and the gate driver circuit(s) 130 are disposed on a side of the display region A in the first direction X, and drives all rows of pixel circuits 20 row by row from a single side of the display region A, forming a single-sided driving manner.

For example, referring to FIG. 4B, the display panel 100 includes gate driver circuits 130. The gate driver circuits 130 are disposed on two opposite sides of the display region A in the first direction X. The two gate driver circuits 130 simultaneously drive all rows of pixel circuits 20 row by row from the two opposite sides of the display region A, forming a double-sided driving manner.

Some embodiments of the present disclosure will be schematically described below by taking the single-sided driving manner as an example, but the implementations of the present disclosure are not limited thereto.

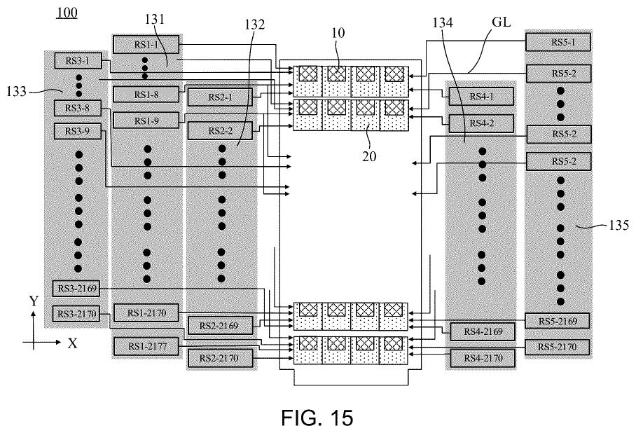

In some embodiments, referring to FIG. 15, the plurality of pixel circuits 20 are arranged in M rows and N columns, each row includes N pixel circuits 20 arranged in the first direction X, and each column includes M pixel circuits 20 arranged in the second direction Y, where M is greater than 1 (M>1), N is greater than 1 (N>1), and M and N are integers. FIG. 15 shows an example in which M is equal to 2170 (M=2170).

In some examples, as shown in FIG. 15, the gate driver circuits 130 include a first gate driver circuit 131, and the first gate driver circuit 131 includes (M+Q) first shift registers RS1 that are in cascade. From a first-stage first shift register RS1 to a last-stage first shift register RS1, the (M+Q) first shift registers RS1 are a 1st first shift register RS1 to an (M+Q)-th first shift register RS1. FIG. 15 shows an example in which Q is equal to 7.

Referring to FIGS. 7 and 15, the first shift register RS1 includes a first signal output terminal. The first reset signal terminals R1 of a P-th row of pixel circuits 20 are connected to the first signal output terminal of a P-th first shift register RS1. The second scan signal terminals G2 of the P-th row of pixel circuits 20 are connected to the first signal output terminal of a (P+Q)-th first shift register RS1. P is greater than or equal to M (P≤M), Q is greater than 0 (Q>0), and P and Q are integers.

It will be noted that the first reset signal terminals R1 and the second scan signal terminals G2 of the P-th row of pixel circuits 20 may be respectively connected to the first signal output terminal of the P-th first shift register RS1 and the first signal output terminal of the (P+Q)-th first shift register RS1 through different gate lines GL.

In this case, the first gate driver circuit 131 may provide the first reset signals for the first reset signal terminals R1 of all the pixel circuits 20 and provide the second scan signals for the second scan signal terminals G2 of all the pixel circuits 20. That is, the first reset signal terminal R1 and the second scan signal terminal G2 of a pixel circuit 20 may share a first gate driver circuit 131, which facilitates the narrow bezel design of the display apparatus 1000 (see FIG. 1).

In some examples, as shown in FIG. 15, the gate driver circuits 130 include a second gate driver circuit 132, and the second gate driver circuit 132 includes M second shift registers RS2 that are in cascade. From a first-stage second shift register RS2 to a last-stage second shift register RS2, the M second shift registers RS2 are a 1st second shift register RS2 to an M-th second shift register RS2.

Referring to FIGS. 7 and 15, the second shift register RS2 includes a second signal output terminal. The second reset signal terminals R2 and the third reset signal terminals R3 of the P-th row of pixel circuits 20 are connected to the second signal output terminal of a P-th second shift register RS2, where P is less than or equal to M (P≤M), and P is an integer.

It will be noted that the second reset signal terminals R2 and the third reset signal terminals R3 of the P-th row of pixel circuits 20 may be connected to the second signal output terminal of the P-th second shift register RS2 through the same gate line GL.

In this case, the second gate driver circuit 132 may provide the second reset signals for the second reset signal terminals R2 of all the pixel circuits 20 and provide the third reset signals for the third reset signal terminals R3 of all the pixel circuits 20. That is, the second reset signal terminal R2 and the third reset signal terminal R3 of a pixel circuit 20 may share the same gate line GL and be connected to the same second gate driver circuit 132, which results in a simple structure and facilitates the narrow bezel design of the display apparatus 1000 (see FIG. 1).

In some examples, as shown in FIG. 15, the gate driver circuits 130 include a third gate driver circuit 133 and a fourth gate driver circuit 134.

As shown in FIGS. 7 and 15, the third gate driver circuit 133 includes M third shift registers RS3 that are in cascade. From a first-stage third shift register RS3 to a last-stage third shift register RS3, the M third shift registers RS3 are a 1st third shift register RS3 to an M-th third shift register RS3. The third shift register RS3 includes a third signal output terminal. The first enable signal terminals EM1 of the P-th row of pixel circuits 20 are connected to the third signal output terminal of a P-th third shift register RS3, where P≤M and P is an integer.

As shown in FIGS. 7 and 15, the fourth gate driver circuit 134 includes M fourth shift registers RS4 that are in cascade. From a first-stage fourth shift register RS4 to a last-stage fourth shift register RS4, the M fourth shift registers RS4 are a 1st fourth shift register RS4 to an M-th fourth shift register RS4. The fourth shift register RS4 includes a fourth signal output terminal. The second enable signal terminals EM2 of the P-th row of pixel circuits 20 are connected to the fourth signal output terminal of a P-th fourth shift register RS4, where P≤M and P is an integer.

It will be noted that the first enable signal terminals EM1 and the second enable signal terminals EM2 of the P-th row of pixel circuits 20 may be respectively connected to the third signal output terminal of the P-th third shift register RS3 and the fourth signal output terminal of the fourth shift register RS4 through different gate lines GL.

In this case, the first enable signal terminal EM1 and the second enable signal terminal EM2 of the pixel circuit 20 are respectively connected to the third gate driver circuit 133 and the fourth gate driver circuit 134 through different gate lines GL. That is, the first enable signal terminal EM1 and the second enable signal terminal EM2 of the pixel circuit 20 are controlled by different gate driver circuits 130, so that the control timing of the first enable signal and the second enable signal is more flexible, which is conducive to improving the control accuracy of the pixel circuit 20.

In some examples, as shown in FIGS. 7 and 15, the gate driver circuits 130 include a fifth gate driver circuit 135, and the fifth gate driver circuit 135 includes M fifth shift registers RS5 that are in cascade. From a first-stage fifth shift register RS5 to a last-stage fifth shift register RS5, the M fifth shift registers RS5 are a 1st fifth shift register RS5 to an M-th fifth shift register RS5. The fifth shift register RS5 includes a fifth signal output terminal. The first scan signal terminals G1 of the P-th row of pixel circuits 20 are connected to the fifth signal output terminal of a P-th fifth shift register RS5, where P≤M and P is an integer.

It will be noted that the first scan signal terminals G1 of the P-th row of pixel circuits 20 may be connected to the fifth signal output terminal of the fifth shift register RS5 through the gate line GL.

In this case, the first scan signal terminal G1 of the pixel circuit 20 is connected to the fifth gate driver circuit 135 through the gate line GL. That is, the first scan signal terminals G1 of the pixel circuits 20 are controlled by a single gate driver circuit 130. The control timing of the first scan signal terminal G1 is more flexible, which is conducive to improving the control accuracy of the pixel circuit 20.

Some embodiments of the present disclosure further provide a driving method of a pixel circuit, which is used for driving the pixel circuit as mentioned in any of the above embodiments. Referring to FIG. 8, a frame F includes a refresh cycle F1, the refresh cycle F1 includes a first reset period P11 and a data writing period P12, and the first reset period P11 precedes the data writing period P12.

It will be understood that a difference between a start time of the data writing period P12 and an end time of the first reset period P11 may be greater than or equal to one row scan time period H, so as to reduce the risk of the rising and falling edges of signals in the first reset period P11 and the data writing period P12 overlapping, which affects data writing or resetting. The row scan time period H may be a duration of an operating voltage of the first scan signal.

As shown in FIGS. 7 and 8, in the first reset period P11, the first reset sub-circuit 23 transmits the first initialization signal received at the first initialization signal terminal INIT1 to the first node N1 in response to the first reset signal received at the first reset signal terminal R1; the second reset sub-circuit 24 transmits the second initialization signal received at the second initialization signal terminal INIT2 to the second node N2 in response to the second reset signal received at the second reset signal terminal R2; and the driving sub-circuit 21 controls the circuit between the second node N2 and the third node N3 to be turned on under the control of the voltage of the first node N1, so as to transmit the second initialization signal to the third node N3.

That is, in the first reset period P11, the first node N1, the second node N2 and the third node N3 are reset to eliminate the influence of the data signal in the previous frame F on the voltages of the first node N1, the second node N2 and the third node N3, thereby improving the display quality.

As shown in FIGS. 7 and 8, when the pixel circuit 20 further includes a third reset sub-circuit 25, in the first reset period P11, the third reset sub-circuit 25 transmits the third initialization signal received at the third initialization signal terminal INIT3 to the fourth node N4 in response to the third reset signal received at the third reset signal terminal R3.

That is, in the first reset period P11, the voltage of the fourth node N4 is reset, so as to eliminate the voltage of the fourth node N4 in the previous frame F, eliminate the difference in voltage of the fourth node N4 caused by the grayscale difference of different sub-pixels P, ameliorate the difference in turn-on speed of the light-emitting devices 10 of different sub-pixels P, and improve the display quality.

In addition, in the first reset period P11, the voltage of the second initialization signal is greater than the voltage of the first initialization signal, so that the voltage of the second node N2 is greater than the voltage of the first node N1. Therefore, the driving sub-circuit 21 is in a strong negative bias state, which may improve the hysteresis effect of the driving sub-circuit 21. As a result, the image sticking is ameliorated, the flicker value of the display panel 100 is reduced, and the problem that the human eye can perceive flickering of the display images is mitigated.

In some embodiments, as shown in FIGS. 7 and 8, the first reset period P11 includes a first sub-period P111 and a second sub-period P112. In the first sub-period P111, the first node N1 is reset. In the second sub-period P112, the second node N2 is reset.

As shown in FIGS. 7 and 8, in the first sub-period P111, the first reset sub-circuit 23 transmits the first initialization signal received at the first initialization signal terminal INIT1 to the first node N1 in response to the first reset signal received at the first reset signal terminal R1. The duration of the first sub-period P111 may be, for example, 6, 7, 8 or 10 row scan time periods H, which is not specifically limited in the embodiments of the present disclosure.

As shown in FIGS. 7 and 8, in the second sub-period P112, the second reset sub-circuit 24 transmits the second initialization signal received at the second initialization signal terminal INIT2 to the second node N2 in response to the second reset signal received at the second reset signal terminal R2. The duration of the second sub-period P112 may be, for example, 6, 10 or 14 row scan time periods H, which is not specifically limited in the embodiments of the present disclosure.

Based on the above, a reset duration of the first node N1 and a reset duration of the second node N2 may be controlled separately, and the timing for controlling the reset of the first node N1 and the reset of the second node N2 is more flexible, which is conducive to improving the reset effect of the first node N1 and the second node N2.

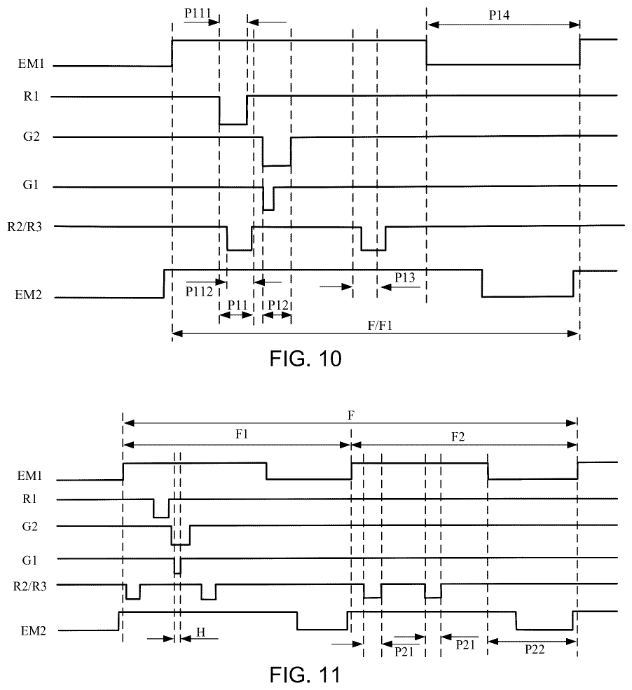

For example, referring to FIGS. 8, 9 and 10, the first sub-period P111 may precede the second sub-period P112 (not shown in FIGS. 8, 9 and 10). Alternatively, as shown in FIG. 8, the first sub-period P111 may follow the second sub-period P112. Alternatively, as shown in FIGS. 9 and 10, the first sub-period P111 and the second sub-period P112 at least partially overlap.

It will be understood that when the first sub-period P111 precedes or follows the second sub-period P112, a difference between the first sub-period P111 and the second sub-period P112 may be greater than or equal to one row scan time period H, so as to reduce the the risk of the rising and falling edges of signals in the first sub-period P111 and the second sub-period P112 overlapping.

For example, as shown in FIGS. 9 and 10, the first sub-period P111 and the second sub-period P112 at least partially overlap, so that the resetting effect of the first node N1 and the second node N2 is good, and the bias voltage of the driving sub-circuit 21 is large, which is more conducive to improving the hysteresis effect of the driving sub-circuit 21, ameliorate the image sticking, reduce the flicker value of the display panel 100, and mitigate the problem that the human eye can perceive flickering of the display images.

As shown in FIGS. 7 and 8, in the data writing period P12, the compensated data signal is written into the first node N1, and the second storage sub-circuit 29 is charged to store the compensated data signal. The duration of the data writing period P12 may be the same as the duration of the first sub-period P111, for example.

In the data writing period P12, the data writing sub-circuit 22 transmits the data signal received at the data signal terminal DATA to the second node N2 in response to the first scan signal received at the first scan signal terminal G1. The driving sub-circuit 21 controls the circuit between the second node N2 and the third node N3 to be turned on under the control of the voltage of the first node N1, so as to transmit the compensated data signal to the third node N3. The compensation sub-circuit 27 transmits the voltage of the third node N3 to the first node N1 in response to the second scan signal received at the second scan signal terminal G2, so as to write the compensated data signal into the first node N1.

In this case, the second storage sub-circuit 29 may store the voltage of the first node N1, playing a role of voltage stabilization, thereby improving the accuracy of the grayscale current signal in the light-emitting periods (the first light-emitting period P14 and the second light-emitting period P22) and improving the display quality.

In some embodiments, referring to FIG. 8, the refresh cycle F1 further includes a second reset period P13 and a first light-emitting period P14, and the second reset period P13 intervenes between the data writing period P12 and the first light-emitting period P14.

It will be understood that a difference between an end time of the data writing period P12 and a start time of the second reset period P13 may be greater than or equal to one row scan time period H, so as to reduce the risk of the rising and falling edges of signals in the second reset period P13 and the data writing period P12 overlapping, which affects data writing or resetting. Moreover, a difference between an end time of the second reset period P13 and a start time of the first light-emitting period P14 may be greater than or equal to one row scan time period H, so as to reduce the risk of the rising and falling edges of signals in the second reset period P13 and the first light-emitting period P14 overlapping, which affects the grayscale current signal.

As shown in FIGS. 7 and 8, in the second reset period P13, the second reset sub-circuit 24 transmits the second initialization signal received at the second initialization signal terminal INIT2 to the second node N2 in response to the second reset signal received at the second reset signal terminal R2, so as to reset the voltage of the second node N2 and eliminate the influence of the written data signal in the data writing period P12 on the voltage of the second node N2. The duration of the second reset period P13 may be, for example, 6, 10 or 14 row scan time periods H, which is not specifically limited in the embodiments of the present disclosure.

In this case, after the data writing period P12, the second node N2 is reset again, which may eliminate the influence of the written data signal in the data writing period P12 on the voltage of the second node N2. In this way, it may be possible to eliminate the deviation of the generated grayscale current signal due to the grayscale difference of different sub-pixels P, and in turn improve the accuracy of the grayscale current signal and improve the display quality.

As shown in FIGS. 7 and 8, when the pixel circuit 20 further includes a third reset sub-circuit 25, in the second reset period P13, the third reset sub-circuit 25 transmits the third initialization signal received at the third initialization signal terminal INIT3 to the fourth node N4 in response to the third reset signal received at the third reset signal terminal R3.

That is, in the second reset period P13, the voltage of the fourth node N4 is reset again. Resetting the fourth node N4 twice may better eliminate the adverse effects of the data signal in the previous refresh cycle F1 and the data writing period P12 on the voltage of the fourth node N4, thereby further improving the display effect.

As shown in FIGS. 7 and 8, in the first light-emitting period P14, the first light-emitting control sub-circuit 281 transmits the first power signal at the first power signal terminal VDD to the second node N2 in response to the first enable signal received at the first enable signal terminal EM1. The driving sub-circuit 21 may generate the grayscale current signal according to the voltage (data signal) of the first node N1 and the voltage (first power signal) of the second node N2, and transmits the grayscale current signal to the third node N3.

On this basis, as shown in FIGS. 7 and 8, the second light-emitting control sub-circuit 282 transmits the voltage (grayscale current signal) of the third node N3 to the fourth node N4 in response to the second enable signal received at the second enable signal terminal EM2, so as to transmit the grayscale current signal to the light-emitting device 10 to drive the light-emitting device 10 to emit light.

As shown in FIGS. 7 and 8, in the first light-emitting period P14, a start time of the operating voltage of the first enable signal may, for example, precede a start time of the operating voltage of the second enable signal. For example, a difference between the start time of the operating voltage of the first enable signal and the start time of the operating voltage of the second enable signal is greater than or equal to one row scan time period H. For example, the difference between the start time of the operating voltage of the first enable signal and the start time of the operating voltage of the second enable signal is two row scan time periods H.

In this case, the first light-emitting control sub-circuit 281 is turned on first, and the driving sub-circuit 21 may generate the grayscale current signal and write the grayscale current signal into the third node N3 in advance. Then, the second light-emitting control sub-circuit 282 is turned on, and the grayscale current signal may be quickly written from the third node N3 into the fourth node N4 to drive the light-emitting device 10. As a result, the display quality of the display panel 100 may be improved.

In addition, as shown in FIGS. 7 and 8, in the first light-emitting period P14, an end time of the operating voltage of the first enable signal, for example, may follow an end time of the operating voltage of the second enable signal. For example, a difference between the end time of the operating voltage of the first enable signal and the end time of the operating voltage of the second enable signal is greater than or equal to one row scan time period H. For example, the difference between the end time of the operating voltage of the first enable signal and the end time of the operating voltage of the second enable signal is one row scan time period H.

In some embodiments, referring to FIG. 11, a frame F includes a refresh cycle F1 and at least one holding cycle F2, and the at least one hold cycle F2 follows the refresh cycle F1. The holding cycle F2 includes at least one third reset period P21 and a second light-emitting period P22, and the at least one third reset period P21 precedes the second light-emitting period P22.

It will be understood that a difference between an end time of the third reset period P21 and a start time of the second light-emitting period P22 may be greater than or equal to one row scan time period H, so as to reduce the risk of the rising and falling edges of signals in the third reset period P21 and the second light-emitting period P22 overlapping, which affects the grayscale current signal.

As shown in FIGS. 7 and 11, in the third reset period P21, the third reset sub-circuit 25 transmits the third initialization signal received at the third initialization signal terminal INIT3 to the fourth node N4 in response to the third reset signal received at the third reset signal terminal R3 to reset the fourth node N4, so as to avoid the threshold voltage shift caused by the long-term bias of the fourth transistor T4 of the driving sub-circuit 21 The duration of the third reset period P21 may be, for example, the same as the duration of the second sub-period P112 or the duration of the second reset period P13.

In addition, resetting the voltage of the fourth node N4 may also eliminate the voltage of the fourth node N4 in the previous refresh cycle F1, eliminate the difference in voltage of the fourth node N4 caused by the grayscale difference of different sub-pixels P, and ameliorate the difference in turn-on speed of the light-emitting devices 10 of different sub-pixels P. As a result, the flicker value of the display panel 100 is reduced, and the problem that the human eye can perceive flickering of the display images is mitigated.

In addition, the voltage of the third reset signal in the refresh cycle F1 is different from the voltage of the third reset signal in the holding cycle F2. In this case, in the third reset period P21, the first storage sub-circuit 26 pulls up or pulls down the voltage of the fourth node N4 in response to the first voltage signal received at the first voltage signal terminal V1. Here, the voltage of one of the first reset signal and the first voltage signal in the refresh cycle F1 is greater than the voltage of one of the first reset signal and the first voltage signal in the holding cycle F2, and the voltage of another of the first reset signal and the first voltage signal in the holding cycle F2 is greater than the voltage of another of the first reset signal and the first voltage signal in the refresh cycle F1.

That is to say, during the process of switching between the refresh cycle F1 and the holding cycle F2, when the voltage of the fourth node N4 is pulled up due to the voltage change of the third reset signal, the first storage sub-circuit 26 pulls down the voltage of the fourth node N4; and when the voltage of the fourth node N4 is pulled down due to the voltage change of the third reset signal, the first storage sub-circuit 26 pulls up the voltage of the fourth node N4.

In this way, the first storage sub-circuit 26 may reduce the influence of the change of the third reset signal on the voltage of the fourth node N4, thereby reducing the sudden change in turn-on brightness of the light-emitting device 10 during the switching between the refresh cycle F1 and the holding cycle F2. As a result, the flicker value of the display panel 100 is reduced, and the problem that the human eye can perceive flickering of the display images is mitigated.

As shown in FIGS. 7 and 11, in the second light-emitting period P22, the first light-emitting control sub-circuit 281 transmits the first power signal at the first power signal terminal VDD to the second node N2 in response to the first enable signal received at the first enable signal terminal EM1. The driving sub-circuit 21 may generate the grayscale current signal according to the voltage (data signal) of the first node N1 and the voltage (first power signal) of the second node N2, and transmits the grayscale current signal to the third node N3.

On this basis, as shown in FIGS. 7 and 11, the second light-emitting control sub-circuit 282 transmits the voltage (grayscale current signal) of the third node N3 to the fourth node N4 in response to the second enable signal received at the second enable signal terminal EM2, so as to transmit the grayscale current signal to the light-emitting device 10 to drive the light-emitting device 10 to emit light.

As shown in FIGS. 7 and 11, in the second light-emitting period P22, a start time of the operating voltage of the first enable signal may, for example, precede a start time of the operating voltage of the second enable signal. For example, a difference between the start time of the operating voltage of the first enable signal and the start time of the operating voltage of the second enable signal is greater than or equal to one row scan time period H. For example, the difference between the start time of the operating voltage of the first enable signal and the start time of the operating voltage of the second enable signal is two row scan time periods H.

In this case, the first light-emitting control sub-circuit 281 is turned on first, and the driving sub-circuit 21 may generate the grayscale current signal and write the grayscale current signal into the third node N3 in advance. Then, the second light-emitting control sub-circuit 282 is turned on, and the grayscale current signal may be quickly written from the third node N3 into the fourth node N4 to drive the light-emitting device 10. As a result, the display quality of the display panel 100 may be improved.

In addition, as shown in FIGS. 7 and 11, in the second light-emitting period P22, an end time of the operating voltage of the first enable signal, for example, may follow an end time of the operating voltage of the second enable signal. For example, a difference between the end time of the operating voltage of the first enable signal and the end time of the operating voltage of the second enable signal is greater than or equal to one row scan time period H. For example, the difference between the end time of the operating voltage of the first enable signal and the end time of the operating voltage of the second enable signal is one row scan time period H.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A pixel circuit, having a first reset period and a data writing period, the first reset period preceding the data writing period, comprising:
a driving sub-circuit connected to a first node, a second node and a third node, wherein the driving sub-circuit is configured to control a circuit between the second node and the third node to be turned on or off under control of a voltage of the first node;
a data writing sub-circuit connected to a first scan signal terminal, a data signal terminal and the second node, wherein the data writing sub-circuit is configured to, in the data writing period, transmit a data signal received at the data signal terminal to the second node in response to a first scan signal received at the first scan signal terminal;
a first reset sub-circuit connected to a first initialization signal terminal, a first reset signal terminal and the first node, wherein the first reset sub-circuit is configured to, in the first reset period, transmit a first initialization signal received at the first initialization signal terminal to the first node in response to a first reset signal received at the first reset signal terminal; and
a second reset sub-circuit connected to a second initialization signal terminal, a second reset signal terminal and the second node, wherein the second reset sub-circuit is configured to, in the first reset period, transmit a second initialization signal received at the second initialization signal terminal to the second node in response to a second reset signal received at the second reset signal terminal; and in the first reset period, a voltage of the second initialization signal is greater than a voltage of the first initialization signal.

2. The pixel circuit according to claim 1, wherein in the first reset period, an absolute value of a difference between the voltage of the second initialization signal and the voltage of the first initialization signal is in a range of 10 V to 13 V, inclusive.

3. The pixel circuit according to claim 1, wherein the pixel circuit further has a second reset period and a first light-emitting period, the second reset period intervening between the data writing period and the first light-emitting period;
the second reset sub-circuit is further configured to, in the second reset period, transmit the second initialization signal received at the second initialization signal terminal to the second node in response to the second reset signal received at the second reset signal terminal.

4. The pixel circuit according to claim 1, wherein the pixel circuit has a first refresh rate and a second refresh rate, and the second refresh rate is less than the first refresh rate; at the first refresh rate, one frame includes one refresh cycle; at the second refresh rate, one frame further includes at least one holding cycle; the at least one holding cycle follows the refresh cycle; the holding cycle includes at least one third reset period and a second light-emitting period; the at least one third reset period precedes the second light-emitting period;
the pixel circuit further comprises:
a third reset sub-circuit connected to a fourth node, a third reset signal terminal and a third initialization signal terminal, wherein the fourth node is configured to be connected to an anode of a light-emitting device; the third reset sub-circuit is configured to, in the first reset period and the third reset period, transmit a third initialization signal received at the third initialization signal terminal to the fourth node in response to a third reset signal received at the third reset signal terminal; and
a first storage sub-circuit connected to a first voltage signal terminal and the fourth node, wherein the first storage sub-circuit is configured to, in the first reset period and the third reset period, pull up or pull down a voltage of the fourth node in response to a first voltage signal received at the first voltage signal terminal;
wherein a voltage of one of the third reset signal and the first voltage signal in the refresh cycle is greater than the voltage of one of the third reset signal and the first voltage signal in the holding cycle; and a voltage of another of the third reset signal and the first voltage signal in the holding cycle is greater than the voltage of another of the third reset signal and the first voltage signal in the refresh cycle.

5. The pixel circuit according to claim 4, wherein a signal of the first voltage signal terminal is the same as a signal of the second initialization signal terminal.

6. The pixel circuit according to claim 4, wherein a signal of the third reset signal terminal is the same as a signal of the second reset signal terminal.

7. The pixel circuit according to claim 4, wherein the first storage sub-circuit includes:
a first capacitor, wherein a first plate of the first capacitor is connected to the first voltage signal terminal, and a second plate of the first capacitor is connected to the fourth node.

8. The pixel circuit according to claim 1, further comprising:
a plurality of third transistors connected in series, wherein control electrodes of the third transistors are connected to the second scan signal terminal; among two third transistors located on two ends of the plurality of third transistors connected in series, a second electrode of one third transistor is connected to the first node, and a first electrode of another third transistor is connected to the third node;
the second reset sub-circuit includes a second transistor; the second transistor and the third transistors are P-type transistors; and a non-operating voltage of the second scan signal received at the second scan signal terminal is less than a non-operating voltage of the second reset signal received at the second reset signal terminal.

9. A display panel, comprising:
a plurality of pixel circuits according to claim 1, wherein the plurality of pixel circuits are arranged in M rows and N columns; each row includes N pixel circuits arranged in a first direction; each column includes M pixel circuits arranged in a second direction; M>1, N>1, and M and N are integers.

10. The display panel according to claim 9, wherein the pixel circuit includes a compensation sub-circuit; in the second direction, from a first row of pixel circuits to a last row of pixel circuits, M rows of pixel circuits are a 1st row of pixel circuits to an M-th row of pixel circuits;
the display panel further comprises:
a first gate driver circuit including (M+Q) first shift registers in cascade, wherein from a first-stage first shift register to a last-stage first shift register, the (M+Q) first shift registers are a 1st first shift register to an (M+Q)-th first shift register;
wherein a first shift register includes a first signal output terminal; first reset signal terminals of a P-th row of pixel circuits are connected to a first signal output terminal of a P-th first shift register; second scan signal terminals of the P-th row of pixel circuits are connected to a first signal output terminal of a (P+Q)-th first shift register; P≤M, Q>0, and P and Q are integers.

11. The display panel according to claim 9, wherein the pixel circuit includes a third reset sub-circuit; in the second direction, from a first row of pixel circuits to a last row of pixel circuits, M rows of pixel circuits are a 1st row of pixel circuits to an M-th row of pixel circuits;
the display panel further comprises:
a second gate driver circuit including M second shift registers in cascade, wherein from a first-stage second shift register to a last-stage second shift register, the M second shift registers are a 1st second shift register to an M-th second shift register; a second shift register includes a second signal output terminal; second reset signal terminals and third reset signal terminals of a P-th row of pixel circuits are connected to a second signal output terminal of a P-th second shift register; P≤M, and P is an integer.

12. The display panel according to claim 9, wherein the pixel circuit includes a first light-emitting control sub-circuit and a second light-emitting control sub-circuit; in the second direction, from a first row of pixel circuits to a last row of pixel circuits, M rows of pixel circuits are a 1st row of pixel circuits to an M-th row of pixel circuits;
the display panel further comprises:
a third gate driver circuit including M third shift registers in cascade, wherein from a first-stage third shift register to a last-stage third shift register, the M third shift registers are a 1st third shift register to an M-th third shift register; a third shift register includes a third signal output terminal; first enable signal terminals of a P-th row of pixel circuits are connected to a third signal output terminal of a P-th third shift register; P≤M, and P is an integer; and
a fourth gate driver circuit including M fourth shift registers in cascade, wherein from a first-stage fourth shift register to a last-stage fourth shift register, and the M fourth shift registers are a 1st fourth shift register to an M-th fourth shift register; a fourth shift register includes a fourth signal output terminal; second enable signal terminals of the P-th row of pixel circuits are connected to a fourth signal output terminal of a P-th fourth shift register; P≤M, and P is an integer.

13. The display panel according to claim 9, wherein in the second direction, from a first row of pixel circuits to a last row of pixel circuits, M rows of pixel circuits are a 1st row of pixel circuits to an M-th row of pixel circuits;
the display panel further comprises:
a fifth gate driver circuit including M fifth shift registers in cascade, wherein from a first-stage fifth shift register to a last-stage fifth shift register, the M fifth shift registers are a 1st fifth shift register to an M-th fifth shift register; a fifth shift register includes a fifth signal output terminal; first scan signal terminals of a P-th row of pixel circuits are connected to a fifth signal output terminal of a P-th fifth shift register; P≤M, and P is an integer.

14. A display apparatus, comprising:
the display panel according to claim 9.

15. A driving method of a pixel circuit, used for driving the pixel circuit according to claim 1, the method comprising the first reset period and the data writing period, wherein the first reset period precedes the data writing period; the first reset period includes a first sub-period and a second sub-period, wherein the first sub-period precedes the second sub-period, or the first sub-period follows the second sub-period, or the first sub-period and the second sub-period at least partially overlap;
in the first sub-period, the first reset sub-circuit transmits the first initialization signal received at the first initialization signal terminal to the first node in response to the first reset signal received at the first reset signal terminal; and
in the second sub-period, the second reset sub-circuit transmits the second initialization signal received at the second initialization signal terminal to the second node in response to the second reset signal received at the second reset signal terminal.

16. The pixel circuit according to claim 1, wherein the first reset sub-circuit includes a plurality of first transistors connected in series; control electrodes of the first transistors are connected to the first reset signal terminal; among two first transistors located on two ends of the plurality of first transistors connected in series, a first electrode of one first transistor is connected to the first initialization signal terminal, and a second electrode of another first transistor is connected to the first node;
the second reset sub-circuit includes a second transistor;
the first transistors and the second transistor are P-type transistors; a non-operating voltage of the first reset signal is less than a non-operating voltage of the second reset signal.

17. The pixel circuit according to claim 1, wherein the pixel circuit further has a light-emitting period; and the pixel circuit further comprises:
a first light-emitting control sub-circuit connected to the second node, a first power signal terminal and a first enable signal terminal, wherein the first light-emitting control sub-circuit is configured to, in the light-emitting period, transmit a first power signal received at the first power signal terminal to the second node in response to a first enable signal received at the first enable signal terminal; and
a second light-emitting control sub-circuit connected to the third node, a fourth node and a second enable signal terminal, wherein the second light-emitting control sub-circuit is configured to, in the light-emitting period, transmit a voltage of the third node to the fourth node in response to a second enable signal received at the second enable signal terminal; the fourth node is configured to be connected to an anode of a light-emitting device;
wherein in the light-emitting period, a start time of an operating voltage of the first enable signal precedes a start time of an operating voltage of the second enable signal.

18. The method according to claim 15, further comprising: a second reset period and a first light-emitting period, the second reset period intervening between the data writing period and the first light-emitting period, wherein
in the second reset period, the second reset sub-circuit transmits the second initialization signal received at the second initialization signal terminal to the second node in response to the second reset signal received at the second reset signal terminal.

19. The method according to claim 15, wherein the pixel circuit further includes a third reset sub-circuit and a first storage sub-circuit; the method further comprises a third reset period;
in the first reset period and the third reset period, the third reset sub-circuit transmits a third initialization signal received at a third initialization signal terminal to a fourth node in response to a third reset signal received at a third reset signal terminal; and the first storage sub-circuit pulls up or pulls down a voltage of the fourth node in response to a first voltage signal received at a first voltage signal terminal.

20. The method according to claim 15, wherein the pixel circuit further includes a first light-emitting control sub-circuit and a second light-emitting control sub-circuit;
the method further comprises a light-emitting period; in the light-emitting period, the first light-emitting control sub-circuit transmits a first power signal received at a first power signal terminal to the second node in response to a first enable signal received at a first enable signal terminal, and the second light-emitting control sub-circuit transmits a voltage of the third node to a fourth node in response to a second enable signal received at a second enable signal terminal; and a start time of an operating voltage of the first enable signal precedes a start time of an operating voltage of the second enable signal.
